(19) United States
(12) Patent Application Publication
(10) Pub. No.: US 2020/0368924 A1
(43) Pub. Date: Nov. 26, 2020

(54) CAPACITIVE CASING ELEMENT FOR ROBOT, ROBOT PROVIDED WITH SUCH A CASING ELEMENT

(71) Applicant: FOGALE NANOTECH, Nîmes (FR)

(72) Inventors: Christian NEEL, Nîmes (FR); Yacine CHAKOUR, Sernhac (FR); Didier ROZIERE, Nîmes (FR)

(21) Appl. No.: 16/636,886

(22) PCT Filed: Jul. 30, 2018
(86) PCT No.: PCT/EP2018/070607

§ 371 Date: Feb. 5, 2020

(30) Foreign Application Priority Data
Aug. 10, 2017 (FR) 1757624

(51) Int. Cl. B25J 19/06; B25J 13/08; G01L 5/00; H03K 17/955

(52) U.S. Cl. CPC B25J 19/06; H03K 17/955; G01L 5/009; B25J 13/081

(57) ABSTRACT

A casing element for a robot, the casing element including:
at least one capacitive electrode, termed a measurement electrode, intended to be biased to a first AC electric potential that is different from a ground potential, at a working frequency;
at least one electrode, termed a guard electrode, arranged beneath the at least one measurement electrode and intended to be biased to an AC electric potential, termed the guard potential, that is identical or substantially identical to the first potential at the working frequency; and —at least one dielectric layer, termed a central dielectric layer, arranged between the at least one measurement electrode and the at least one guard electrode. A robot is also provided with at least such a casing element.

### TECHNICAL FIELD

The present invention relates to a capacitive trim element for a robot. It also relates to a robot provided with such (a) capacitive trim element(s).

The field of the invention is, non-limitatively, that of the field of robotics, in particular the field of industrial robotics or service robots, for example medical or domestic robots, or also collaborative robots, also called “cobots”.

### STATE OF THE ART

Industrial or domestic robots, in particular cobots, generally comprise a body on which a functional head is fastened, presented in the form of a tool or a tool-holder, allowing them to carry out one or more tasks within an environment.

To be able to use or move a robot or cobot, such as for example a robotized arm, within an environment including humans and/or objects, or in cooperation with humans, it is necessary to provide it with the capability to detect these humans and objects located within its environment, to avoid any risk of accident. A recent solution for providing this detection capability consists of fitting a robot with capacitive sensors which are sensitive to approach or contact.

However, there are many old robots still in use which were not fitted with detection capability at the time of their design/manufacture. It is therefore necessary to find a solution making it possible to retrofit these robots with a detection functionality in a way that is simple, inexpensive and not very time-consuming.

In addition, robots are tools with a very long service life. As a result, for robots that are provided with a detection functionality, there is also a need to replace trim elements, while retaining this detection functionality.

An aim of the present invention is to meet at least one of these needs.

Another aim of the present invention is to propose a capacitive trim element capable of being used to retrofit an existing robot with a capacitive detection functionality in a way that is simple, rapid and inexpensive.

Another aim of the present invention is to propose a capacitive trim element capable of being used to replace a trim element of a robot fitted with a capacitive detection functionality, in a way that is simple, rapid and inexpensive, while retaining said functionality.

### DISCLOSURE OF THE INVENTION

At least one of these aims is achieved with a trim element for a robot, in particular provided to be positioned on a segment or an articulation of a robot in place of, or in addition to, a trim element of said robot, said trim element comprising:
at least one capacitive electrode, called measurement electrode, provided to be polarized at a first alternating electrical potential different from a ground potential at a working frequency,
at least one electrode, called guard electrode, arranged beneath said at least one measurement electrode, and provided to be polarized at an alternating electrical potential, called guard potential, identical or substantially identical to said first potential at said working frequency, and
at least one dielectric layer, called central layer, arranged between said at least one measurement electrode and said at least one guard electrode.

Thus, the present invention proposes a trim element comprising an integrated capacitive detection functionality. The trim element according to the invention makes it possible to add a capacitive detection functionality to a robot which was not initially provided with such a functionality, in a way that is simple, rapid and inexpensive. In addition, as the detection and guard electrodes form part of the trim element, it is not necessary to modify the architecture of the robot.

Furthermore, the trim element according to the invention can be used to replace a trim element of a robot that already has a detection functionality, without disturbing this detection functionality. Servicing and maintenance of the trim elements of a robot already provided with a capacitive detection functionality becomes simple, rapid and avoids lengthy and expensive down time of the robot.

In the present application, two alternating potentials are identical at a given frequency when they each comprise an alternating component that is identical or similar at this frequency. Thus, at least one of the two potentials that are identical at said frequency can also comprise a direct component, and/or an alternating component with a frequency different to said given frequency.

Similarly, two alternating potentials are different at the working frequency when they do not have an alternating component that is identical or similar at this working frequency.

In the present application, the term “ground potential” or “general ground potential”, denotes a reference potential of the electronics, of the robot or of its environment, which can be for example an electrical earth or a ground potential. This ground potential can correspond to an earth potential, or to another potential, connected or not to the earth potential.

Furthermore it is noted that generally, objects which are not in direct electrical contact with a particular electrical potential (electrically floating objects) tend to be polarized by capacitive coupling at the electrical potential of other objects present in their environment, such as for example earth or electrodes, if the surface areas of overlap between these objects and those of the environment (or the electrodes) are sufficiently large.

In the present application “object” denotes any object or person that may be located within the environment of the robot.

By “robot” is meant any robotized system, and in particular a robotized arm, a wheeled vehicle such as a truck equipped with an arm or a handling system, or a robot of the humanoid type or fitted with movement members such as limbs.

According to a particularly advantageous characteristic, the trim element according to the invention can also comprise at least one dielectric layer, called external layer, arranged over the measurement electrode(s).

Such an external layer makes it possible to protect the measurement electrodes against mechanical impacts, soiling and liquids, and thus increases the service life of the measurement electrodes.

Such an external layer can be a layer fastened to the measurement electrodes, with no air or gap present between the measurement electrodes and said external layer: thus the measurement electrodes, and consequently the capacitive detection, are not disturbed by capacitances due to parasitic coupling between the dielectric external layer and ground (especially if this external layer has a high dielectric permittivity).

For example, such an external layer can be a plastic layer, a layer of varnish, a layer of glue, or any other dielectric material or coating.

Alternatively, such an external layer can be independent and dismantled/removed at will.

It can be for example a rigid casing. It can be produced for example by moulding or by thermoforming.

According to an embodiment, the trim element can comprise a rigid, semi-rigid or resilient external layer, and a central layer in the form of a separate element modelled to be inserted into the external layer, and comprising on its faces, respectively, said at least one measurement electrode and said at least one guard electrode.

The central layer can be, or comprise, a rigid or semi-rigid plastic material, shaped for example by moulding or thermoforming. The measurement and guard electrodes can be produced by deposition or spraying, as previously described, on the already shaped central layer.

Thus, the trim element is presented as a double-casing structure, with an outer casing (the external layer) which ensures the mechanical protection and the central layer which supports the electrodes.

According to another particularly advantageous characteristic, the trim element can comprise a layer, called bearing layer, arranged beneath the guard electrode(s) and provided to come into contact with a surface of the robot.

Such a bearing layer makes it possible to protect the at least one guard electrode, but also to electrically isolate from a surface on which the trim element is positioned.

The bearing layer can be a continuous layer, or formed by an assembly of separate bearing elements, such as studs or pins.

The bearing layer can be dielectric, in particular when the surface of the robot on which it comes into contact is electrically conductive.

The bearing layer can be bonded to the central layer or to the at least one guard electrode, with or without a gap.

Advantageously, the bearing layer can be produced from a material that is locally deformable, flexible and/or elastic, such as a foam.

Such a flexible bearing layer allows on the one hand shock-absorption of external impacts and on the other hand absorption of the surface differences/discontinuities present on a surface of the robot on which the trim element is positioned. This characteristic is particularly beneficial when the trim element is presented in the form of an additional part, or cladding piece, provided to be positioned over an original trim part of the robot.

The bearing layer can comprise apertures, or recesses, in the trim element provided facing electrical/electronic components, such as for example detection electronics, connecting wires, etc. so as not to apply any stress on said components.

The bearing layer can also be rigid or semi-rigid or resilient. In this case it can be for example arranged in order to maintain a flexible and/or elastic central layer in position and shape against a rigid or resilient external layer.

Advantageously, the trim element can be constituted by layers (in particular the external layer, the central layer and the bearing layer) arranged so as to optimize thermal conductivity. This can be achieved in particular by using materials having a high thermal conductivity, and/or assembling them so as to optimize thermal contact (for example avoiding air gaps between materials). Optimization of thermal conductance is important to avoid unduly degrading the exhaustion of heat generated by the component parts of the robot.

Advantageously, the trim element according to the invention can comprise a positioning means, or an index mark, making it possible to mount said trim element in a position and orientation that are or can be determined, onto a part of the robot.

Such a positioning means can be any element that can constitute a positioning and orientation index mark for positioning the trim element on a part of the robot, such as a segment or an articulation of the robot.

Such a positioning means can also be any element with a guiding function that enforces placing the trim element on the robot in a particular determined position.

For example, such a positioning means can be a specific shape of the trim element, in particular a specific shape of the cross section of said trim element.

Alternatively or in addition, such a positioning means can be:
a visual index mark, such as a positioning and orientation mark;

and/or
a mechanical index mark, such as a pin, indexing slot, tab or also a positioning and orientation aperture; and/or
a fastening means of the screw or clip type, etc.; and/or a mechanical interface that is complementary or adapted to a mechanical interface of the robot.

The positioning means is an important element of the invention, as it makes it possible to position the trim element in a determined position on the robot, and thus the position of the measurement electrodes is known in the robot indexing system. Now, awareness of the position of the electrodes is essential for efficient use of their measurements.

The trim element can preferentially comprise several measurement electrodes, in particular placed in a matrix configuration.

In addition, the trim element according to the invention can comprise an individual guard electrode for each measurement electrode.

Alternatively, the trim element according to the invention can comprise a guard electrode common to several measurement electrodes, in particular to all the measurement electrodes. Such a common guard element can form a guard plane common to several, in particular all, the measurement electrodes.

Such a guard plane can also be used as a shielding layer for the electrical/electronic component parts located in the robot, so as to ensure electromagnetic compatibility between the robot and its environment.

According to an embodiment, the trim element, or at least one layer chosen from the central layer, the external layer and the bearing layer, can be modelled to obtain the desired shape. The modelling can be carried out for example by thermoforming, by moulding, etc.

Alternatively, the trim element, or at least one layer chosen from the central layer, the external layer and the bearing layer, can be printed by 3D printing.

At least one measurement electrode, respectively at least one guard electrode, can be arranged on the central layer by spraying metallic particles, with the use of a mask, or by screen printing or also by ink jet.

When the trim element comprises a single guard electrode, forming a guard plane, said guard electrode can be produced by deposition of a conductive layer, for example by painting.

Each of these deposition steps can be before or after a step of shaping/modelling the central layer, as applicable.

According to an embodiment, the dielectric central layer can be presented in the form of a double-face printed circuit.

In this case, according to an advantageous configuration, the measurement electrode(s) can be arranged on one of the faces of said printed circuit, and the guard electrode(s) can be arranged on the opposite face of said printed circuit. Thus, the dielectric forming the printed circuit forms a support layer for the measurement and guard electrodes.

The measurement and guard electrodes can then be produced by conventional techniques for producing printed circuits, such as photolithography and etching.

The printed circuit can be produced on a flexible substrate of the polyimide type. It can also be produced on an extensible or deformable substrate, for example by thermoforming, to generate surfaces with several radii of curvature (spherical, etc.).

The printed circuit can be bonded to the external layer such that there is no gap between the printed circuit and the external layer.

The bonding can be thermal bonding or bonding by use of an adhesive product.

The printed circuit can comprise numerous pins projecting from the face comprising the at least one guard electrode, and forming the bearing layer.

According to another embodiment, the measurement electrodes and the guard electrodes can be produced on separate substrates, optionally stacked with an intercalated dielectric element. In this case, the central layer can be constituted by one or two layers of these stacked substrates, and any intercalated element.

This or these substrates can be single-face printed circuit substrates, or any other type of substrate making it possible to support electrodes, such as for example substrates that can be deformed by thermoforming, elastic, flexible, textile, etc.

Of course, these embodiments can be combined. It is for example possible to have measurement electrodes produced with a printed circuit and one or more guard electrodes produced by a deposition technique on a face of the central layer.

Furthermore, generally, the central layer can be composed of a plurality of layers of material.

The trim element according to the invention can also comprise at least one detection electronics configured to measure a signal with respect to a coupling capacitance, called electrode-object capacitance, between at least one measurement electrode and a nearby object.

Such detection electronics are well known in the state of the art for capacitive detection.

According to an embodiment, at least one detection electronics can comprise a charge amplifier configured to supply an output voltage representative of the capacitance between a measurement electrode and a nearby object.

The trim element according to the invention can comprise dedicated detection electronics for each measurement electrode.

Alternatively, or in addition, the trim element according to the invention can comprise detection electronics common to several, or all, the measurement electrodes. In this case, said detection electronics can also comprise a polling means for polling said measurement electrodes individually or per unit.

Such a polling means can for example comprise a switch connecting the charge amplifier to each of the measurement electrodes in turn.

According to a particularly advantageous configuration, the trim element according to the invention can comprise several detection electronics groups, distributed over said trim element, and at a distance from one another.

This configuration makes it possible to better manage cases of partial damage of the trim element according to the invention. In fact, in this configuration, when a part of the trim element is damaged, the other parts of the element continue to function and to provide the capacitive detection functionality.

Each detection electronics group can comprise one or more detection electronics. Each detection electronics can be dedicated to one measurement electrode or to a unit with several measurement electrodes.

At least one detection electronics can be arranged on a separate printed circuit board. This separate printed circuit board can be an independent board, firmly fixed or not to the trim element, and connected to the trim element by a connection interface, in particular wired or in the form of a ribbon cable constituted by the dielectric central layer supporting conductive traces.

According to an embodiment, at least one detection electronics can be placed between the external layer and a guard electrode.

In this embodiment, the detection electronics can be arranged on a separate printed circuit board. The measurement electrodes and the guard electrodes can be produced on separate substrates. The substrate with the guard electrode can be arranged so as to cover the detection electronics totally or partially.

Alternatively, or in addition, at least one detection electronics can be produced by a part of a printed circuit supporting measurement and/or guard electrodes, at the periphery of these electrodes.

At least one detection electronics can be arranged on the central layer. In particular, when the central layer is formed by a printed circuit, at least one detection electronics can be provided on a face of said printed circuit.

Alternatively or in addition, at least one detection electronics can comprise at least one element arranged on the central layer (such as a charge amplifier), and at least one element arranged on a separate printed circuit board (such as demodulation, filtering, digitization elements, etc.).

According to an embodiment, at least one detection electronics can be arranged on the same side as the at least one guard electrode, with respect to the central layer.

This embodiment allows good protection of the detection electronics, in particular from external impacts.

Alternatively or in addition, at least one detection electronics can be arranged on the same side as the at least one measurement electrode, with respect to the central layer. This embodiment makes it possible to guard said detection electronics at the guard potential by the at least one guard electrode, and thus avoid leakage capacitances or disturbances that could degrade the capacitive detection functionality.

According to a particularly advantageous characteristic, at least one, in particular each, detection electronics can be guarded at the guard potential by a guard wall, or cover, or also volume, polarized at the guard potential.

Thus, the detection electronics is protected from leakage capacitances, and more generally from electromagnetic disturbances, which would degrade the detection functionality.

This embodiment is particularly beneficial when the detection electronics is positioned on the side of the guard with respect to the central layer, or independently from the trim element according to the invention.

When the detection electronics is arranged on the side of the measurement electrodes, and opposite one or more guard electrodes, it is not necessary to use an additional guard wall (or cover, or volume or layer), as said measurement electronics is already guarded by the at least one guard electrode, at least with respect to couplings with the internal elements of the robot. The guard electrode then constitutes the guard wall of the electronics.

It should be noted that one guard wall can also be formed by a conductive layer of the detection electronics circuit.

The trim element according to the invention can also comprise at least one wired and/or wireless connection interface.

This connection interface can for example be arranged to receive at least one alternating electrical potential. This alternating electrical potential can:
correspond to the first alternating potential, the guard potential, or both;
be used to obtain the first alternating potential, the guard potential, or both.

This alternating electrical potential can for example originate from a master oscillator and be transmitted to all the trim elements of a robot, so that they all appear at the same guard potential with respect to one another.

This connection interface can also be arranged to transmit a measurement or detection signal to another device, or appliance, such as for example a logic controller of a robot.

According to an advantageous characteristic, the at least one measurement electrode can be separated from the at least one guard electrode by a locally elastically compressible layer, so that a bearing pressure exerted on said trim element locally modifies the distance between the measurement and guard electrodes.

Such a compressible layer can be the central layer, or an additional layer in addition to the central layer.

Such a compressible layer makes it possible to modify locally, and elastically, the distance between at least one measurement electrode and the at least one guard electrode when an object exerts pressure or bears on the trim element.

The distance, in particular the distance variation, between the measurement and guard electrodes makes it possible to characterize, in particular to measure, the bearing pressure exerted, as a function of the compressibility of the compressible layer.

A signal that can be measured at the level of the bearing position for characterizing the pressure exerted, can be a signal relating to, or representative of, the resistance, called inter-electrode resistance, between the measurement and guard electrodes. In this case, it is necessary to polarize the measurement and guard electrodes with a potential difference. In addition, it is necessary for the compressible layer to be electrically conductive, with a variable conductance as a function of pressure, for example by piezoresistive effect.

Alternatively, or in addition, a signal that can be measured at the level of the bearing position for characterizing the pressure exerted, can be a signal relating to, or representative of, the capacitance, called inter-electrode capacitance, between the measurement and guard electrodes.

In this case, it is necessary to polarize the measurement and guard electrodes with an alternating potential difference, at the measuring frequency. In addition, it is necessary for the compressible layer to be dielectric.

The trim element according to the invention can comprise at least one electronics for detecting a signal with respect to the inter-electrode capacitance, or the inter-electrode resistance, between the measurement and guard electrodes, at the level of said bearing.

When the measured signal relates to the inter-electrode capacitance, this detection electronics can be partially or totally common with the electronics for the detection of the electrode-object capacitance.

The trim element according to the invention can be presented in the form of:
a rigid or resilient casing;
a flexible cover provided to be fastened on a trim element of said robot.

The trim element according to the invention can be presented in the form of:
an additional casing, or a cover, provided to be mounted on an existing casing of a robot; or
a replacement casing, provided to be mounted in place of an existing casing.

According to an advantageous embodiment, the trim element can comprise two parts, provided to be positioned on either side of a segment or an articulation of the robot, and being fastened together.

The two parts can be independent of one another before they are positioned on the robot.

Alternatively, the two parts can be fastened to one another about a rotary shaft, via a hinge, and moveable with respect to one another so that they can be:
opened to position the trim element around a segment, or an articulation, of the robot, then
closed.

In all cases, the trim element is preferentially mounted in a fixed manner on the robot.

Fastening the trim element can be carried out:
by bonding, screwing or clipping on a surface of the robot;
by at least one fastening means of the suction type; and/or
by at least one magnetic/magnetized fastening means.

Alternatively, or in addition, the trim element can comprise at least one means of fastening by clamping around a portion of the robot.

According to another aspect of the invention, a robot is proposed, provided with at least one trim element according to the invention.

In the robot according to the invention, the at least one trim element according to the invention can be used as a replacement or in addition to an already existing trim element.

The robot according to the invention can be a robot that is initially provided, or not, with a capacitive detection functionality.

### DESCRIPTION OF THE FIGURES AND EMBODIMENTS

Other advantages and characteristics will become apparent on examination of the detailed description of examples that are in no way limitative, and from the attached drawings in which:

FIGS. 1, 2, 3a and 3b are schematic representations in cross section of three embodiments of a trim element according to the invention;

FIGS. 4a-4c are schematic representations of a robot fitted with two trim elements according to the invention;

FIGS. 5a and 5b are schematic representations of two embodiments of a set of detection electronics capable of being implemented with a trim element according to the invention; and

FIGS. 6-7 are schematic representations in cross section of two other embodiments of a trim element according to the invention.

It is well understood that the embodiments which will be described hereinafter are in no way limitative. Variants of the invention can be envisaged comprising only a selection of the characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In particular, all the variants and all the embodiments described can be combined together if there is no objection to this combination from a technical point of view.

In the figures, elements common to several figures retain the same reference.

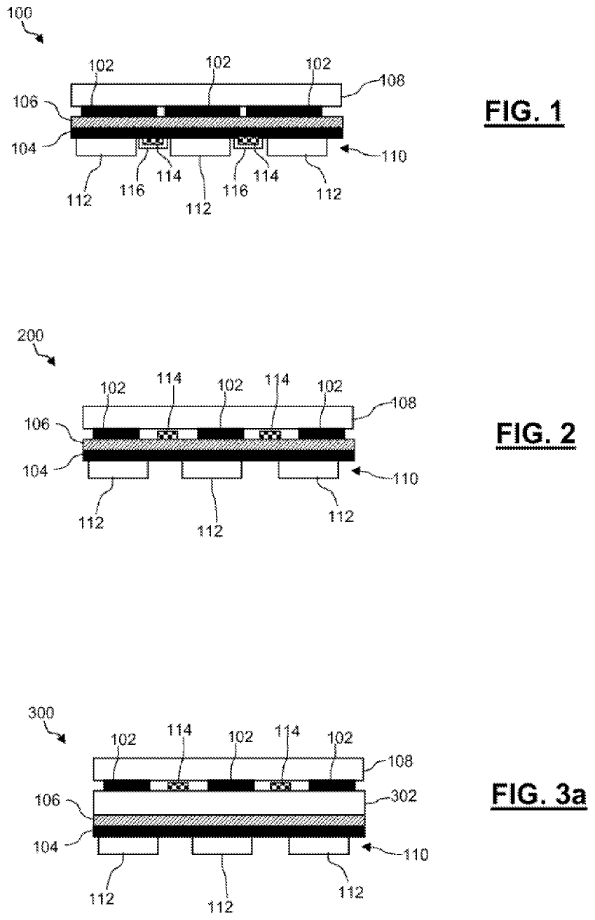

FIG. 1 is a schematic representation in cross section of a first non-limitative embodiment of a trim element according to the invention.

The trim element 100, shown in FIG. 1, is a rigid casing that can be used either in place of an existing casing on a robot, or in addition to an existing casing. In this latter case, the trim element 100 is positioned on the existing casing.

The trim element 100 can be used for fitting to a segment of a robot or an articulation of a robot.

The trim element 100 comprises several capacitive electrodes 102, called measurement electrodes, and a capacitive electrode 104, called guard electrode, common to the set of measurement electrodes. The guard electrode 104 forms a guard plane covering substantially all the measurement electrodes 102.

The trim element 100 also comprises a dielectric layer 106, called central layer, positioned between the measurement electrodes 102 and the guard electrode 104.

The central layer 106 can be produced by a printed circuit, rigid or flexible, on which are deposited, or etched, the measurement electrodes 102 and the guard electrode 104.

Alternatively, the central layer 106 can be produced from plastic by 3D printing, or by moulding, or also by thermoforming of a substantially flat plastic plate.

The measurement electrodes 102 can then be deposited on the central layer 106 by:

spraying metallic particles onto said central layer 106 after having positioned a mask on said central layer;
printing of the ink jet type, or
screen printing.

The guard electrode 104 can also be deposited on the central layer 106 by painting said central layer 106 with a layer of conductive material.

The trim element 100 also comprises a dielectric layer 108, called external layer, positioned on the measurement electrodes 102. This external layer 108 is intended to protect the measurement electrodes from external damage such as by impacts, moisture or liquids. This external layer 108 can be bonded on the measurement electrodes 102 or can be produced by depositing a coating on said measurement electrodes 102, such as for example a plastic coating, varnish, etc.

The external layer 108 is preferably in contact with the measurement electrodes 102 such that there is no free space (or at least no significant air gap) between said external layer 108 and the measurement electrodes 102.

According to an example embodiment, the external layer 108 can be produced in the form of a rigid, semi-rigid or resilient casing. The central layer 106 can be produced (by moulding, thermoforming or 3D printing) in the form of a rigid, semi-rigid or resilient casing having a complementary shape for insertion into the external layer 108, and comprising on its faces the measurement electrodes 102 and the guard electrode 104.

According to another example embodiment, the external layer 108 can be produced in the form of a rigid, semi-rigid or resilient casing. The central layer 106 can be produced in the form of a double-face printed circuit board with the measurement electrodes 102 and the guard electrode 104.

Optionally, the trim element 100 also comprises a dielectric layer 110, called bearing layer, positioned beneath the guard electrode 104. This bearing layer 110 is intended to:
protect the guard electrode 104, and/or
isolate the guard electrode 104 from a conductive surface on which the trim element 100 is positioned, and/or
absorb the surface discontinuities when the trim element 100 is positioned on a surface of a robot, and/or
absorb any impacts that may occur on the trim element during its use.

The bearing layer 110 can be produced from a flexible material, such as flexible plastic or foam for example.

The bearing layer 110 can be constituted by layers or coatings of insulation materials.

In the example shown in FIG. 1, the bearing layer 108 is produced by an assembly of separate bearing elements 112 such as bearing pins or legs.

The trim element 100 also comprises electronic modules 114, arranged between the bearing elements 112, below the level of the bearing elements, and in particular on the central layer 106, and on the same face as the guard electrode 104.

In the embodiment presented, the bearing elements 112 of the bearing layer 108 also serve to protect the electronic modules 114 mechanically. The electronic modules 114 are at a distance from one another. Each electronic module 114 comprises at least one detection electronics used for:
polarizing the measurement electrodes 102, with a first alternating electrical potential different from a ground potential of the robot at the working frequency, and
polarizing the guard electrode 104 with an alternating electrical potential V_{G}, called guard potential, identical to the first potential, at the working frequency.

Each detection electronics comprises at least one electronic component configured to supply an output signal representative of the capacitance between a measurement electrode 102 and a nearby object.

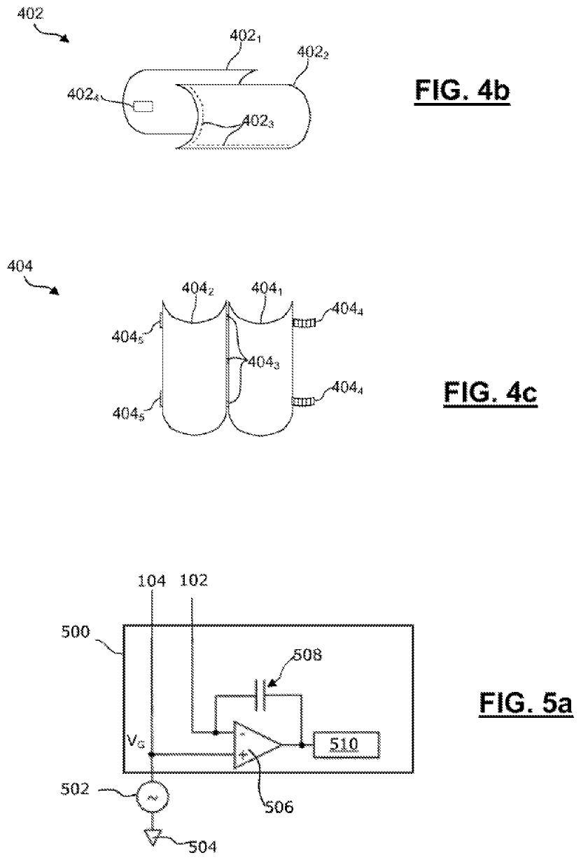

Examples of detection electronics are given in greater detail hereinafter with reference to FIGS. 5a and 5b.

In order to protect each electronic module 114 from any leakage capacitances, the trim element 100 comprises a cover 116, called guard cover, polarized at the guard potential V_{G} and covering each electronic module 114. The polarization at the guard potential of each cover 116 can be carried out by electrically connecting each cover 116 to the guard electrode 104, itself polarized at the guard potential V_{G}.

It should be noted that the cover 116 is not necessarily an external element. It can be produced by a guard wall, for example formed by a layer or a plane of the printed circuit of the electronic module 114.

FIG. 2 is a schematic representation in cross section of another non-limitative embodiment of a trim element according to the invention.

The trim element 200 in FIG. 2 comprises all the elements of the trim element 100 in FIG. 1.

In addition, unlike the trim element 100 in FIG. 1, in the trim element 200 the electronic modules are positioned on the central layer 106 on the side of the measurement electrodes 102, in particular on the face of the central layer 106 comprising the measurement electrodes 102. In this configuration, it is not necessary to use additional guard covers as the electronic modules 114 are guarded at the guard potential by the guard electrode 104, polarized at the guard potential V_{G} and which in fact constitutes a guard wall for the electronic modules.

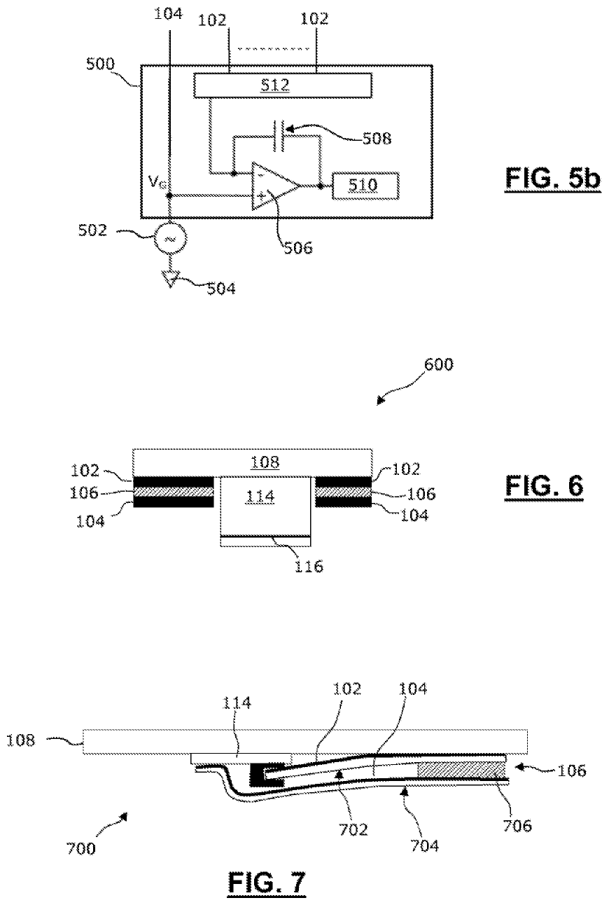

FIG. 6 is a schematic representation in cross section of another non-limitative embodiment of a trim element according to the invention.

The trim element 600 in FIG. 6 comprises measurement electrodes 102, the guard electrode(s) 104, the central layer 106, the external layer 108, the electronic module(s) 114.

In the example shown in FIG. 6, the electronic modules 114 are produced in the form of printed circuits separate from the central layer 106 comprising the measurement electrodes 102 and the guard electrode 104. The electronic modules 114 are positioned at the level of this central layer 106 in one or more apertures made through this central layer 106, or on the edges of this central layer 106. The electronic modules 114 can thus be fastened on the external layer 108. They are connected to the measurement electrodes 102 and to the guard electrodes 104 for example by ribbon cables produced with the substrate of the central layer 106. Preferably, the electronic module(s) 114 comprise a guard wall 116 in the form of a layer of the printed circuit.

FIG. 7 is a schematic representation in cross section of another non-limitative embodiment of a trim element according to the invention.

The trim element 700 in FIG. 7 comprises the measurement electrodes 102, the guard electrode(s) 104, the central layer 106, the external layer 108, the electronic module(s) 114.

In the example shown in FIG. 7, the measurement electrodes 102 are produced with a single-face printed circuit 702.

The guard electrode(s) 104 are also produced with a single-face printed circuit 704.

The central layer 106 is constituted by a substrate of at least one of the single-face printed circuits 702 and 704, and as shown in the example illustrated in FIG. 7, an intercalated element 706 placed between said printed circuits.

The electronic module(s) 114 are produced in the form of printed circuits separate from the central layer 106. They are fastened on the external layer 108. They are placed between the external layer 108 and the single-face printed circuit 704 with the guard electrodes 104, and connected to the measurement electrodes 102 and to the guard electrode 104. Thus, the electronic module(s) 114 are protected by the guard electrodes 104.

FIGS. 3a and 3b are schematic representations in cross section of another non-limitative embodiment of a trim element according to the invention.

The trim element 300, shown in FIGS. 3a and 3b, comprises all the elements of the trim element 200 in FIG. 2.

The trim element 300 also comprises a layer 302 that is locally elastically compressible, arranged between the central layer 106 and the measurement electrodes 102. This layer is for example produced from very flexible plastic or foam. This compressible layer 302 makes it possible to vary locally the distance between the measurement electrodes 102 and the guard electrode 104, when a load is brought to bear on the trim element 300.

FIG. 3a shows the trim element 300 at rest and FIG. 3b shows the trim element 300 when a pressure, represented by the arrow 304, is applied thereto.

Thus, by measuring the capacitance between the measurement electrodes 102 and the guard electrode 104 it is possible to characterize the pressure exerted. To this end, it is necessary to set the measurement 102 and guard 104 electrodes to different alternating potentials, at the working frequency, at least at the level of the bearing position. To this end, one of the measurement 102 and guard 104 electrodes can be grounded. Alternatively, or in addition, an alternating electrical potential that is non-zero at the working frequency can be introduced between the guard electrode 104 and the measurement electrode 102.

As an alternative to what has just been described in FIGS. 1, 2, 3a and 3b, the trim element can comprise an individual guard electrode for each measurement electrode, in place of the single guard electrode forming a guard plane.

Furthermore, it is possible for the detection electronics not to be arranged in the trim element but independently, for example on a printed circuit board independent of the trim element.

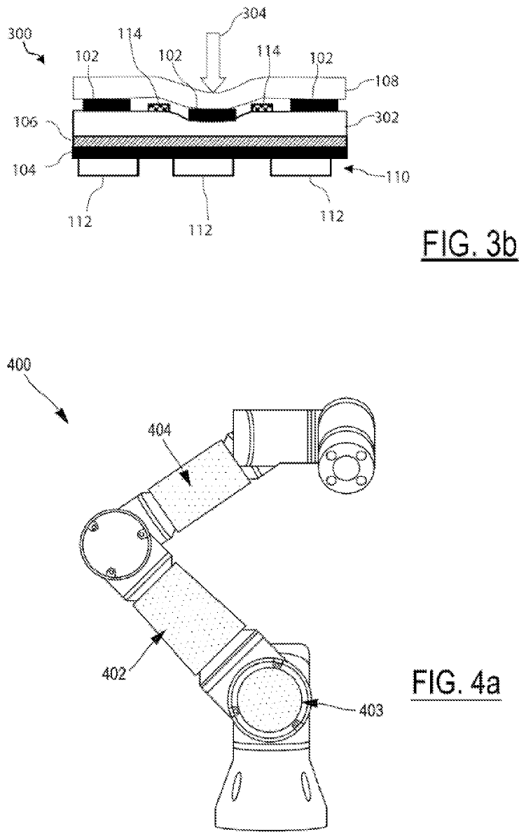

FIG. 4a is a schematic representation of a robot fitted with trim elements according to the invention.

The robot 400 is a robotized arm comprising several segments connected together by rotary articulations.

The robot 400 comprises three trim elements 402, 403 and 404 according to the invention, each fitted to a segment or an articulation of the robot, either in place of an original trim element of the robot, or in addition to an original trim element.

The trim element 403 is a cover that is fastened on an articulation of the robot 400, replacing an existing cover. It therefore fastens into the fastening interfaces (for example threadings or screws) of the original cover.

FIG. 4b is a schematic representation of the trim element 402 fitted to a segment of the robot 400.

The trim element 402 has two identical parts 402₁ and 402₂ with a cross section in the form of a half-cylinder. Each part 402₁ and 402₂ is provided to be fastened to the segment of the robot 400 by bonding. Alternatively, each part can be fastened to the segment of the robot by screwing, clipping or by suction-type means, provided on the trim element or on the segment of the robot.

Visual index marks 402₃, provided on the external faces of the parts 402₁ and 402₂, make it possible to position and correctly orient each part 402₁ and 402₂ of the trim element 402 when it is assembled onto the segment of the robot.

The trim element 402 also comprises a mechanical positioning element 402₄ in the form of a stud or an element in relief intended to be inserted into a groove or a machined indentation on the robot 400.

FIG. 4c is a schematic representation of the trim element 404 fitted to another segment of the robot 400.

The trim element 404 has two identical parts 404₁ and 404₂ with a cross zsection in the form of a half-cylinder. The parts 404₁ and 404₂ are assembled together by a hinge 404₃ allowing mutual rotation between said parts 404₁ and 404₂ such that said parts 404₁ and 404₂ can be open in order to position the trim element around the segment of the robot 400, then closed.

The part 404₁ comprises one or more assembly means 4044, such as a collar or a clip, being introduced into (or abutting against) an assembly means 404₅ such as an aperture or a tab or also a lip 404₅, provided on the part 404₂, in order to carry out assembly by clamping the trim element 404 around the segment of the robot.

Visual index marks (not shown), provided on the external faces of the trim element 404 make it possible to position and correctly orient it when it is assembled onto the segment of the robot.

The trim element 404 can also comprise a mechanical positioning element similar to the element 402₄ of the trim element 402, in the form of a stud or an element in relief intended to be inserted into a groove or a machined indentation on the robot 400.

FIG. 5a is a schematic representation of a first embodiment of detection electronics capable of being implemented in a trim element according to the invention.

The detection electronics 500, shown in FIG. 5a, can be, or can be incorporated in, an electronic module 114 in FIGS. 1, 2, 3a and 3b. The detection electronics 500 can be produced in an analogue or digital form, or an analogue/digital combination.

The detection electronics 500 receives an alternating excitation voltage, denoted V_{G}, from an oscillator 502 referenced to a ground potential 504. The voltage V_{G} is used as guard potential for polarizing the guard electrode(s) 104, and as first potential for polarizing the measurement electrode(s) 102.

The detection electronics 500 comprises a current or charge amplifier, represented by an operational amplifier 506 and a negative-feedback capacitor 508. In the embodiment shown, this charge amplifier supplies at the output a voltage proportional to the coupling capacitance between an electrode 102 and an object in proximity.

The detection electronics 500 also comprises a conditioner 510 making it possible to obtain a signal representative of the sought coupling capacitance Cₑₒ, and/or the presence or of the proximity of an object or a body. This conditioner 510 can comprise, for example, a synchronous demodulator for demodulating the signal with respect to a carrier, at a working frequency. The conditioner 510 can also comprise an asynchronous demodulator or an amplitude detector. This conditioner 510 can, of course, be produced in an analogue and/or digital form (microprocessor) and comprise all necessary means for filtering, conversion, processing, etc.

The detection electronics 500 can be dedicated to one measurement electrode 102 so that each measurement electrode comprises its own detection electronics.

Alternatively, and as shown in FIG. 5b, the detection electronics 500 can be common to several measurement electrodes 102.

In this case, the detection electronics 500 also comprises a polling means 512 connecting the charge amplifier 506, in turn, to each measurement electrode 102, so as to poll individually each of said measurement electrodes 102.

Of course, the measurement electronics 500 can comprise components other that those described.

The detection electronics 500, or at least its sensitive part with the charge amplifier 506 can be referenced (or supplied by electrical feeds referenced) to the guard potential V_{G}, in order to minimize parasitic capacitances.

The detection electronics 500 can also be referenced, more conventionally, to the ground potential 504.

Of course, the invention is not limited to the examples that have just been described, and numerous modifications may be made to these examples without departing from the scope of the invention.

1. A trim element for a robot, in particular provided to be positioned on a segment or an articulation of a robot in place of or in addition to a trim element of said robot said trim element comprising:
at least one capacitive electrode, called measurement electrode, provided to be polarized at a first alternating electrical potential different from a ground potential at a working frequency;
at least one electrode, called guard electrode, arranged beneath said at least one measurement electrode and provided to be polarized at an alternating electrical potential (V_{G}), called guard potential, identical or substantially identical to said first potential at said working frequency; and
at least one dielectric layer, called central layer, arranged between said at least one measurement electrode and said at least one guard electrode.

2. The trim element according to claim 1, characterized in that it comprises at least one dielectric layer, called external layer, arranged over the measurement electrode(s).

3. The trim element according to claim 2, characterized in that it comprises a rigid, semi-rigid or resilient external layer, and a central layer in the form of a separate element modelled to be inserted into the external layer, and comprising on its faces, respectively, said at least one measurement electrode and said at least one guard electrode.

4. The trim element according to any claim 1, characterized in that it comprises a layer, called bearing layer, arranged beneath the guard electrode(s) and provided to come into contact with a surface of the robot.

5. The trim element according to claim 1, characterized in that it comprises a positioning means, or an index mark, making it possible to mount said trim element on a part of the robot, in a position and orientation that are, or can be, determined.

6. The trim element according to claim 1, characterized in that the central layer is presented in the form of a double-face printed circuit, the measurement electrode(s) being arranged on one of the faces of said printed circuit, and the guard electrode(s) being arranged on the opposite face of said printed circuit.

7. The trim element according to claim 1, characterized in that it comprises at least one detection electronics configured to measure a signal with respect to a coupling capacitance, called electrode-object capacitance, between at least one measurement electrode and a nearby object.

8. The trim element according to claim 7, characterized in that it comprises several detection electronics units, distributed over said trim element, at a distance from one another.

9. The trim element according to claim 2, characterized in that at least one detection electronics is placed between the external layer and a guard electrode.

10. The trim element according to claim 7, characterized in that at least one detection electronics is placed on the central layer.

11. The trim element according to claim 7, characterized in that at least one detection electronics is guarded at the guard potential (V_{G}) by a guard wall or cover, polarized at the guard potential (V_{G}).

12. The trim element according to claim 1, characterized in that it comprises at least one wired and/or wireless connection interface arranged for:
receiving at least one alternating electrical potential corresponding to the first alternating potential or the guard potential (V_{G}) or both; and/or
transmitting a measurement or detection signal.

13. The trim element according to claim 1, characterized in that the at least one measurement electrode is separated from the at least one guard electrode by a locally elastically compressible layer, so that a bearing pressure on said trim element locally modifies the distance between the measurement and guard electrodes.

14. The trim element according to the claim 13, characterized in that it comprises at least one electronics for the detection of a signal relating to the capacitance and/or the resistance, called inter-electrode capacitance and/or resistance, between the measurement and guard electrodes at the level of said bearing pressure.

15. The trim element according to claim 1, characterized in that it is presented in the form of:
a rigid or resilient casing; or
a flexible cover provided to be fastened on a trim element of said robot.

16. The trim element according to claim 1, characterized in that it is presented in the form of:
an additional casing, or a cover, provided to be mounted on an existing casing of a robot; or
a replacement casing provided to be mounted in place of an existing casing.

17. The trim element according to claim 1, characterized in that it comprises two parts, provided to be positioned on either side of a segment or an articulation of the robot, and being fastened together.

18. A robot equipped with at least one trim element according to claim 1.
